(19) United States
(12) Patent Application Publication
(10) Pub. No.: US 2010/0099263 A1
(43) Pub. Date: Apr. 22, 2010

(54) NF3/H2 REMOTE PLASMA PROCESS WITH HIGH ETCH SELECTIVITY OF PSG/BPSG OVER THERMAL OXIDE AND LOW DENSITY SURFACE DEFECTS

(75) Inventors: Chien-Teh Kao, Sunnyvale, CA (US); Xinliang Lu, Fremont, CA (US); Haichun Yang, Santa Clara, CA (US); Zhenbin Ge, Fremont, CA (US); David T. Or, Santa Clara, CA (US); Mei Chang, Saratoga, CA (US)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS, INC., Santa Clara, CA (US)

(21) Appl. No.: 12/254,716

(22) Filed: Oct. 20, 2008

(51) Int. Cl. H01L 21/34; H01L 21/465; H01L 21/428

(52) U.S. Cl. 438/703; 438/735; 438/707; 257/E21.485; 257/E21.475; 257/E21.46

(57) ABSTRACT

A method and apparatus for selectively etching doped semiconductor oxides faster than undoped oxides. The method comprises applying dissociative energy to a mixture of nitrogen trifluoride and hydrogen gas remotely, flowing the activated gas toward a processing chamber to allow time for charged species to be extinguished, and applying the activated gas to the substrate. Reducing the ratio of hydrogen to nitrogen trifluoride increases etch selectivity. A similar process may be used to smooth surface defects in a silicon surface.

### BACKGROUND OF THE INVENTION

1. Field of the Invention

Embodiments of the invention relate to methods of treating semiconductor substrates. More particularly, embodiments of the invention provide methods of selectively etching layers on semiconductor substrates.

2. Description of the Related Art

Doped silicates are widely used in the semiconductor industry for many applications. They may be used as interlayer insulators in some cases, or as semiconductive regions for CMOS devices. In some cases they are formed by depositing a doped layer on a substrate, while in other cases they may be formed by implanting dopants into a substantially pure semiconductor layer. In many instances, doped silicates are used alongside pure silicates to provide a chemical difference by which treatment of the different materials may be differentiated.

In some instances, a doped silicate layer may be used as an etch-stop layer for an undoped silicate layer. In those cases, an etching chemistry is used that etches the undoped silicate layer, but etches the doped layer at a much lower rate or not at all. In other cases, a doped silicate layer may be used as a protective or sacrificial layer over an undoped thermal or plasma formed oxide layer. Removal of the doped silicate layer in those cases is preferably performed with a chemistry that etches the doped layer without etching the undoped layer.

In other instances, a doped silicate layer may be deposited in a recess formed in a substantially pure semiconductor substrate, such as in epitaxial source/drain formation. If the doped silicate layer is over-deposited, that is if the deposited doped layer protrudes above the surrounding surface of the substrate, it may be necessary to etch the doped layer to a common level with the substrate. A chemistry having selectivity for the doped layer over the undoped layer is preferred for such etching.

In most cases, the doped silicate layers referred to above use boron and phosphorus as dopants. Chemistries are known that provide very high etch selectivity for boron and phosphorus doped silicates over pure silicates, but these chemistries generally involve fluorocarbons, which bring carbon as a potential impurity. The presence of carbon in undesired circumstances can degrade the properties of devices, such as increasing their resistance or changing their dielectric properties. In such cases, there remains a need for a method of selectively etching a substrate having doped and undoped regions with a carbon-free chemistry.

### SUMMARY OF THE INVENTION

Embodiments of the invention provide a method for treating a semiconductor substrate having doped regions and undoped regions, comprising disposing the semiconductor substrate in a processing chamber, providing a reactive gas mixture comprising hydrogen radicals and fluorine radicals to the processing chamber, exposing the semiconductor substrate to the reactive gas mixture, and etching the doped regions of the semiconductor substrate faster than the undoped regions in a carbon-free dry etch process.

Other embodiments provide a method of processing a substrate, comprising disposing the substrate in a processing chamber, depositing a doped silicate glass layer on the substrate, depositing an undoped silicate glass layer on the substrate, and etching the deposited layers using a carbon-free dry etch process having an etch selectivity of the doped silicate glass layer over the undoped silicate glass layer of at least 1.2.

Still other embodiments provide a method of treating a semiconductor substrate, comprising disposing the substrate in a substrate processing chamber, forming a reactive gas mixture comprising neutral hydrogen radicals and fluorine radicals in a remote activation chamber, flowing the reactive gas mixture toward a substrate processing chamber for a time interval sufficient to extinguish charged species, exposing a surface of the substrate to the reactive gas mixture, and smoothing defects in the surface of the substrate by reacting the reactive gas mixture with oxides in the surface of the substrate. In some embodiments, the reactive gas mixture also comprises hydrogen fluoride.

### BRIEF DESCRIPTION OF THE DRAWINGS

So that the manner in which the above-recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a flow diagram summarizing a method according to one embodiment of the invention.

FIG. 2 is a flow diagram summarizing a method according to another embodiment of the invention.

FIG. 3 is a flow diagram summarizing a method according to another embodiment of the invention.

FIG. 4 is a cross-sectional view of an apparatus according to an embodiment of the invention.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments of the invention generally provide methods and apparatus for selectively etching semiconductor substrates having doped and undoped silicate regions. In one aspect, a method for selectively etching such substrates comprises disposing the semiconductor substrate in a processing chamber, providing a reactive gas mixture comprising hydrogen radicals and fluorine radicals to the processing chamber, exposing the semiconductor substrate to the reactive gas mixture, and etching the doped regions of the semiconductor substrate faster than the undoped regions. The semiconductor substrate may have doped and undoped silicate regions, or may have only a doped surface or an undoped surface to be etched. The doped regions or surface will generally be doped with boron or phosphorus atoms or ions, and may be formed by implanting dopants into a semiconductor surface or by deposition with in-situ doping, such as by an epitaxial deposition process.

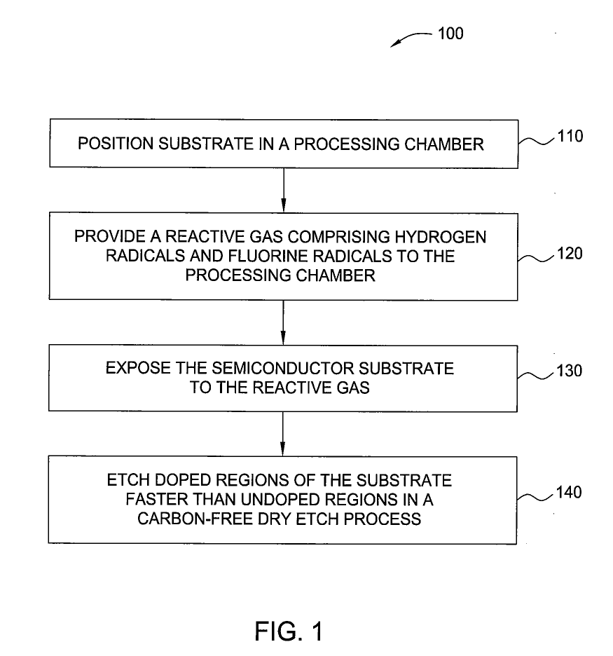

FIG. 1 is a flow diagram summarizing a method 100 according to one embodiment of the invention. A substrate is positioned in a processing chamber at 110. At 120, a reactive gas comprising hydrogen radicals and fluorine radicals is provided to the processing chamber using carbon-free precursors.

The hydrogen and fluorine radicals are generally formed by applying dissociative energy to a precursor gas mixture. The dissociative energy may be any type of energy chosen to accomplish the selected reaction, such as RF energy, laser, microwave, or electrical energy. In one embodiment, the precursor gas mixture is exposed to microwave energy to dissociate molecules comprising hydrogen and fluorine into hydrogen and fluorine radicals. In another embodiment, the precursor gas may be exposed to RF energy to dissociate the molecules.

Neutral species are generally preferred for the selective etching process. Because the dissociative energy may create charged ions, in some embodiments it may be advantageous to apply the dissociative energy at a location remote to the processing chamber and flow the active species toward the processing chamber for a time sufficient to extinguish electrical charges. Hydrogen ions will recombine with electrons to make hydrogen radicals or molecules, or they may combine with fluoride ions or other negatively charged ions to neutralize the electrical charge. As electrical charges are extinguished from the reactive gas mixture, the activated species become limited to neutral radicals. In some embodiments, it may be advantageous to filter any remaining fugitive charged species inside, or just outside, the processing chamber by applying a weak electrical bias to accelerate the charged particle to a charge collection zone.

Referring again to FIG. 1, the reactive gas is directed toward the substrate at 130. The active species in the reactive gas react with the oxides and the dopants in the substrate surface, removing material selectively. Doped regions are generally etched faster than undoped regions in a carbon-free dry etch process at 140. Use of a carbon-free process avoids carbon contamination, and a dry etch process allows high etch selectivity.

In one embodiment, a selective etch process or a reactive etch process is performed on a substrate. The substrate may have layers of oxide material of different types, such as native oxide, grown oxide, thermal oxide, plasma-formed oxide, doped oxide, doped silicate glass, and undoped silicate glass. Doped oxides may be doped with boron, phosphorus, or arsenic. A selective etch process may be used to remove doped oxides at a higher rate than the undoped oxides. In some cases, a selective etch process may remove doped silicate glass at a rate at least 20% higher than undoped silicate glass. The selectivity of the selective etch process may be controlled by adjusting ratios of etchants applied to the substrate. Following selective etching, a smoothing etch process may also be performed on the substrate to smooth roughness left by the selective etch process.

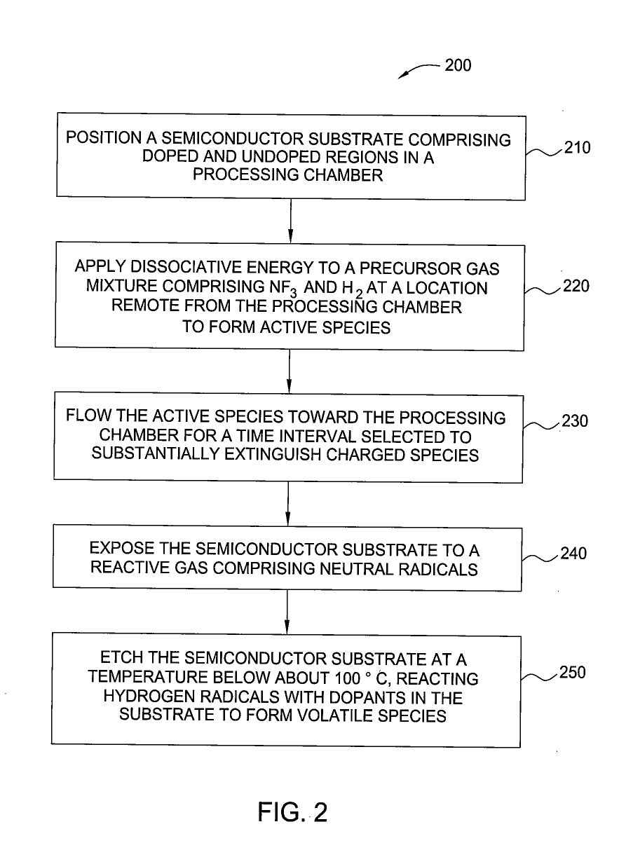

FIG. 2 is a flow diagram summarizing a method 200 according to another embodiment. The exemplary selective etch method 200 of FIG. 2 removes doped oxides at a higher rate than undoped oxides on a surface of the substrate using a precursor gas mixture comprising nitrogen trifluoride (NF₃) and hydrogen (H₂). The method 200 begins at 210 by placing a substrate into a plasma etch processing chamber. During processing, the substrate may be cooled below 65° C., such as between 15° C. and 50° C. In another example, the substrate is maintained at a temperature of between 22° C. and 40° C., such as about 35° C.

The hydrogen gas and nitrogen trifluoride gas are introduced into an activation chamber to form a reactive gas mixture at 220. The amount of each gas introduced into the chamber is variable and may be adjusted to control etch selectivity, or to accommodate, for example, the thickness of the oxide layer to be removed, the geometry of the substrate being cleaned, the volume capacity of the plasma and the volume capacity of the chamber body. In one aspect, the gases are added to provide a gas mixture having at least a 1:1 molar ratio of hydrogen to nitrogen trifluoride. In another aspect, the molar ratio of the gas mixture is at least about 3:1 (hydrogen to nitrogen trifluoride). Preferably, the gases are introduced in the activation chamber at a molar ratio of from about 1:1 (hydrogen to nitrogen trifluoride) to about 30:1, more preferably, from about 5:1 (hydrogen to nitrogen trifluoride) to about 30:1. More preferably, the molar ratio of the gas mixture is of from about 5:1 (hydrogen to nitrogen trifluoride) to about 10:1. The molar ratio of the gas mixture may also fall between about 10:1 (hydrogen to nitrogen trifluoride) and about 20:1. Alternatively, a pre-mixed gas mixture of the preferred molar ratio may be provided to the activation chamber.

The ratio of hydrogen to nitrogen trifluoride may be adjusted to control etch selectivity. Hydrogen generally attacks the dopants in the doped oxide materials, while fluorine combines with hydrogen and nitrogen to attack silicates. Etch selectivity for doped or heavily doped layers may be enhanced using a lower ratio of hydrogen to nitrogen trifluoride, and will depend on the degree of doping in the doped oxide layer. Etch rate will depend on the absolute concentration of etchants in the gas mixture.

The activation chamber applies dissociative energy to the precursor gas mixture. The dissociative energy may be microwave energy, RF power, a static electric field, laser energy, or any other type of energy devised to dissociate molecules of the precursor gas. The molecules generally dissociate into ions, electrons, and radicals in a reactive gas mixture. Electrical charges are preferably extinguished before applying the reactive gas mixture to the substrate because the charged species generated by the process tend to implant into the surface rather than remove material from the surface, and can cause damage to the surface of the substrate. For this reason, it is preferred to recombine charged species into uncharged species before being applied to a substrate.

At 230, the reactive gas mixture is formed at a location remote from the processing chamber and flowed toward the processing chamber for a time interval sufficient to allow charged species to extinguish. Ions may recombine with other ions or electrons in the reactive gas mixture. For example, hydrogen ions may recombine with electrons to form hydrogen radicals. Hydrogen ions may also recombine with fluoride ions to form hydrogen fluoride. Hydrogen, nitrogen, and fluorine ions will also cluster together to form various species, of which one notable variety is the ammonium hydrofluoride radical (NH₄F.HF), which reacts with silicon oxides to form ammonium hexafluorosilicate ((NH₄)₂SiF₆), ammonia, and water. Nitrogen, hydrogen, and fluorine ions may also combine to form highly reactive ammonium fluoride (NH₄F), which also reacts with silicon oxides to form ammonium hexafluorosilicate. Ammonia and water are volatile, but ammonium hexafluorosilicate is a solid at room temperature, and sublimes at slightly higher temperatures, as discussed below. The remaining neutral radicals in the reactive gas impinge upon the substrate at 240. The impinging active species etch the substrate at 250. In the embodiment of FIG. 2, the substrate temperature is kept below about 100° C., such as below about 75° C., for example below about 50° C., to enhance the overall etch rate by increased etching of oxides by ammonium species. Higher etch temperatures will increase etch selectivity for doped oxides over undoped oxides, at the expense of lower overall etch rate, because formation of the ammonium hexafluorosilicate film is reduced at higher temperatures.

In some embodiments, charged species may be filtered out of the reactive gas before it is applied to the substrate. In one example, an electrical bias may be applied to the walls of the processing chamber in which the substrate is disposed. The electrical bias diverts charged species toward a chamber wall, preventing it from impinging the substrate. In another example, an electromagnetic filter may be placed outside the processing chamber along the pathway carrying the reactive gas mixture to the processing chamber. This electromagnetic filter may take the form of a parallel plate electrode powered by DC or RF power to create an electrical bias.

A purge gas or carrier gas may be added to the gas mixture. Any suitable purge/carrier gas may be used, such as argon, helium, hydrogen, nitrogen, forming gas, or mixtures thereof. Typically, the overall gas mixture by volume of hydrogen and nitrogen trifluoride is within a range from about 0.05% to about 20%. The remainder of the process gas may be the carrier gas. In one embodiment, the purge or carrier gas is first introduced into the activation chamber before the other precursor gases to stabilize the pressure within the chamber body. In addition to helping manage the chamber pressure, the purge or carrier gas may also help form the desired neutral reactive species by providing more electron density in the initial mixture to combine with reactive species.

The operating pressure within the chamber body can be variable. The pressure may be maintained within a range from about 500 mTorr to about 30 Torr, preferably, from about 1 Torr to about 10 Torr, and more preferably, from about 3 Torr to about 6 Torr. A RF power within a range from about 5 watts to about 600 watts may be applied to ignite a plasma of the gas mixture within the activation chamber. Preferably, the RF power is less than about 100 watts. More preferable is that the frequency at which the power is applied is very low, such as less than about 100 kHz, and more preferably, within a range from about 50 kHz to about 90 kHz.

Not wishing to be bound by theory, it is believed that hydrogen and fluorine radicals in the reactive gas mixture react with dopants in the doped oxide region to form volatile species such as phosphines (PₓH₃ₓ), boranes (BₓH₃ₓ), arsine (AsH₃), and fluorides of phosphorus, boron, and arsenic (PF₃, BF₃, AsF₃, AsF₅), depending on which dopants are present. Because these reactions proceed at a faster rate than the etching of oxides by ammonium/fluorine radicals, an etchant mixture with hydrogen radicals will etch a doped substrate faster than an undoped substrate. Also, because some of the hydrogen ions combine to form species that etch only oxide and do not remove dopants, and because the relative concentration of the oxide etchants is far less than that of the dopant etchants, reducing the hydrogen content reduces oxide etch rate faster than dopant etch rate.

The thin film of ammonium hexafluorosilicate on the substrate surface may be removed during a vacuum sublimation process. The processing chamber radiates heat to dissociate or sublimate the thin film of ammonium hexafluorosilicate into volatile SiF₄, NH₃, and HF products. In one example, a portion of the process chamber positioned above the substrate may be heated to a temperature of at least about 150° C., such as about 180° C. or higher, to transmit heat to the substrate. These volatile products are then removed from the chamber by the vacuum pump attached to the system. In one example, a temperature of about 75° C. or higher is used to effectively sublimate and remove the thin film from the substrate. Preferably, a temperature of about 100° C. or higher is used, such a temperature within a range from about 115° C. to about 200° C. Once the film has been removed from the substrate, the chamber is purged and evacuated prior to removing the cleaned substrate.

In some instances, the vacuum sublimation process may be combined with another thermal process, so that the thin film of ammonium hexafluorosilicate is removed at a temperature above 200° C. The substrate may be heated to an anneal temperature such as 500-800° C., or more, in some instances. The heating energy for such embodiments may be applied using a radiant source, such as a laser, flash lamp, or halogen lamp. In other instances, the heating energy may be applied to the back side of the substrate, that is the side opposite the ammonium hexafluorosilicate film.

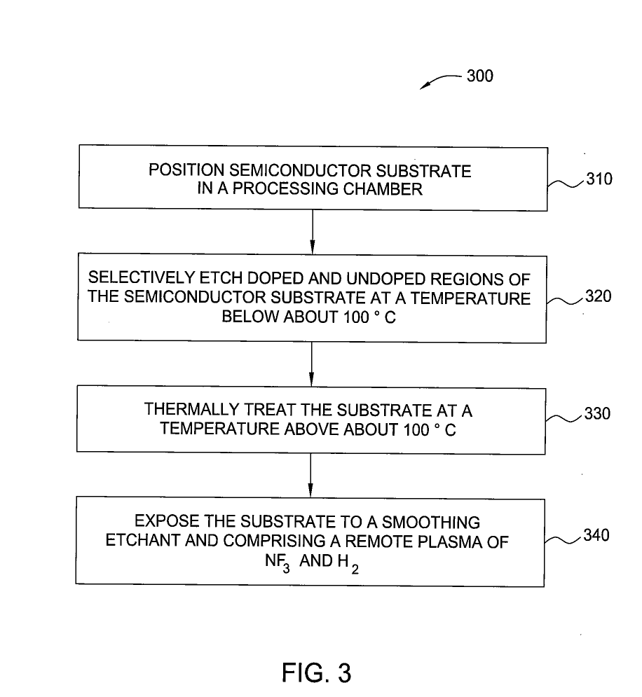

In one embodiment, a dry etch process may be used to smooth surface defects in an exposed silicon region of a substrate. FIG. 3 is a flow diagram summarizing a method 300 according to another embodiment of the invention. At 310, a substrate is positioned in a processing chamber. At 320, the substrate is exposed to a selective etch process at a temperature below about 100° C. to remove oxides from the substrate. The selective etch process of 320 may be any dry etching process, but will preferably comprise exposing the substrate to a reactive gas comprising activated radicals of ammonia and nitrogen trifluoride. The selective etch process of FIG. 3 may be performed in the same chamber as the selective etch process of FIG. 2, or in a specially adapted chamber. In most respects, however, the selective etch process of FIG. 3 is similar to that of FIG. 2, with ammonia gas replacing hydrogen gas. The selective etch process of 320 forms a layer of ammonium hexafluorosilicate on the substrate, which is removed in a thermal treatment step at 330. The thermal treatment step is performed as described in the previous paragraph, leaving an exposed silicon surface. In some cases, the exposed silicon surface will have defects that must be removed for subsequent processes.

At 340, the substrate is then exposed to a smoothing etchant to remove the surface defects. The smoothing etchant of 340 is a remotely formed plasma comprising nitrogen trifluoride and hydrogen gas. As described above, the plasma is substantially free of charged particles, but contains reactive radical species which etch the surface and remove non-uniformities. The smoothing etch process may be conducted at similar conditions as the selective etch process.

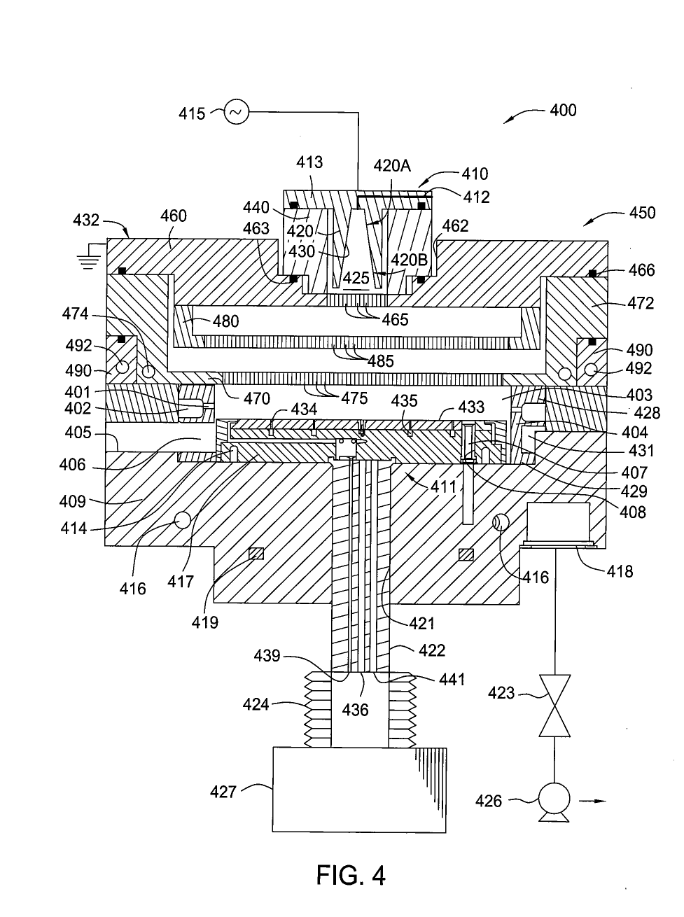

A selective etching process may be performed using a vacuum chamber, such as a SICONI™ chamber available from Applied Materials, Inc., located in Santa Clara, Calif. FIG. 4 is a partial cross-sectional view of a processing chamber 400 according to one embodiment of the invention. In this embodiment, processing chamber 400 includes lid assembly 450 disposed at an upper end of chamber body 409, and support assembly 411 at least partially disposed within chamber body 412. The processing chamber 400 and the associated hardware are preferably formed from one or more process-compatible materials, such as aluminum, anodized aluminum, nickel plated aluminum, nickel plated aluminum 6061-T6, stainless steel, as well as combinations and alloys thereof, for example.

The chamber body 409 includes a slit valve opening 405 formed in a sidewall thereof to provide access to the interior of the processing chamber 400. The slit valve opening 405 is selectively opened and closed to allow access to the interior of the chamber body 409 by a suitable substrate handling robot (not shown). In one embodiment, a substrate can be transported in and out of the processing chamber 400 through the slit valve opening 405 to an adjacent transfer chamber and/or load-lock chamber, or another chamber within a cluster tool.

In one or more embodiments, the chamber body 409 includes a channel 416 formed therein for flowing a heat transfer fluid therethrough. The heat transfer fluid can be a heating fluid or a coolant and is used to control the temperature of the chamber body 409 during processing and substrate transfer. The temperature of the chamber body 409 is important to prevent unwanted condensation of the gas or byproducts on the chamber walls. Exemplary heat transfer fluids include water, ethylene glycol, or a mixture thereof. An exemplary heat transfer fluid may also include nitrogen gas.

The chamber body 409 can further include a liner 404 that surrounds the support assembly 411. The liner 404 is preferably removable for servicing and cleaning. The liner 404 can be made of a metal such as aluminum, or a ceramic material. However, the liner 404 can be any process compatible material. The liner 404 can be bead blasted to increase the adhesion of any material deposited thereon, thereby preventing flaking of material which results in contamination of the processing chamber 400. In one or more embodiments, the liner 404 includes one or more apertures 401 and a pumping channel 402 formed therein that is in fluid communication with a vacuum system. The apertures 401 provide a flow path for gases into the pumping channel 402, which provides an egress for the gases within the processing chamber 400.

The vacuum system can include a vacuum pump 426 and a throttle valve 423 to regulate flow of gases through the processing chamber 400. The vacuum pump 426 is coupled to a vacuum port 418 disposed on the chamber body 409, and is therefore in fluid communication with the pumping channel 402 formed within the liner 404. The terms “gas” and “gases” are used interchangeably, unless otherwise noted, and refer to one or more precursors, reactants, catalysts, carrier, purge, cleaning, combinations thereof, as well as any other fluid introduced into the chamber body 409.

In the embodiment of FIG. 4, the liner 404 includes an upper portion 428 and a lower portion 429. An aperture 406 that aligns with the slit valve opening 405 disposed on a side wall of the chamber body 409 is formed within the liner 404 to allow entry and egress of substrates to/from the chamber body 409. Typically, the pumping channel 402 is formed within the upper portion 428. The upper portion 428 also includes the one or more apertures 401 formed therethrough to provide passageways or flow paths for gases into the pumping channel 402.

The apertures 401 allow the pumping channel 402 to be in fluid communication with a processing zone 403 within the chamber body 409. The processing zone 403 is defined by a lower surface of the lid assembly 450 and an upper surface of the support assembly 411, and is surrounded by the liner 404. The apertures 401 may be uniformly sized and evenly spaced about the liner 404. However, any number, position, size or shape of apertures may be used, and each of those design parameters can vary depending on the desired flow pattern of gas across the substrate receiving surface as is discussed in more detail below. In addition, the size, number and position of the apertures 401 are configured to achieve uniform flow of gases exiting the processing chamber 400. Further, the aperture size and location may be configured to provide rapid or high capacity pumping to facilitate a rapid exhaust of gas from the chamber 400. For example, the number and size of apertures 401 in close proximity to the vacuum port 418 may be smaller than the size of apertures 401 positioned farther away from the vacuum port 418.

The lower portion 429 of the liner 404 includes a flow path or vacuum channel 431 disposed therein. The vacuum channel 431 is in fluid communication with the vacuum system described above. The vacuum channel 431 is also in fluid communication with the pumping channel 402 via a recess or port (not shown in the cross-section of FIG. 4) formed in an outer diameter of the liner 404 and connecting the vacuum channel 431 and the pumping channel 402. Generally, two such portals are formed in an outer diameter of the liner 404 between the upper portion 428 and the lower portion 429. The portals provide a flow path between the pumping channel 402 and the vacuum channel 431. The size and location of each portal is a matter of design, and are determined by the stoichiometry of a desired film, the geometry of the device being formed, the volume capacity of the processing chamber 400 as well as the capabilities of the vacuum system coupled thereto. Typically, the portals are arranged opposite one another or 180 degrees apart about the outer diameter of the liner 404.

In operation, one or more gases exiting the processing chamber 400 flow through the apertures 401 formed through the upper portion 428 of the liner 404 into the pumping channel 402. The gas then flows within the pumping channel 402 and into the vacuum channel 431. The gas exits the vacuum channel 431 through the vacuum port 418 into the vacuum pump 426.

Support assembly 411 is partially disposed within chamber body 412, and positions a substrate for processing. Support assembly 411, comprising support member 417, is raised and lowered by shaft 422 which is enclosed by bellows 424. Chamber body 409 includes slit valve opening 406 formed in a sidewall thereof to provide access to the interior of processing chamber 400. Slit valve opening 406 is selectively opened and closed to allow access to the interior of chamber body 409 by a substrate handling robot (not shown). In one embodiment, a substrate may be transported in and out of processing chamber 400 through slit valve opening 406 to an adjacent transfer chamber and/or load-lock chamber (not shown), or another chamber within a cluster tool. Illustrative cluster tools include but are not limited to the PRODUCER®, CENTURA®, ENDURA®, and ENDURA SL™ platforms, available from Applied Materials, Inc., located in Santa Clara, Calif.

Chamber body 409 also includes channel 416 formed therein for flowing a heat transfer fluid therethrough. The heat transfer fluid may be a heating fluid or a coolant and is used to control the temperature of chamber body 409 during processing and substrate transfer. The temperature of chamber body 409 is important to prevent unwanted condensation of the gas or byproducts on the chamber walls. Exemplary heat transfer fluids include water, ethylene glycol, or a mixture thereof. An exemplary heat transfer fluid may also include nitrogen gas.

Chamber body 409 further includes a liner 404 that surrounds support assembly 411, and is removable for servicing and cleaning. Liner 404 is preferably made of a metal such as aluminum, or a ceramic material. However, other materials which are compatible may be used during the process. Liner 404 may be bead blasted to increase the adhesion of any material deposited thereon, thereby preventing flaking of material which results in contamination of processing chamber 400. Liner 404 typically includes one or more apertures 401 and a pumping channel 402 formed therein that is in fluid communication with a vacuum system. Apertures 401 provide a flow path for gases into pumping channel 402, and the pumping channel provides a flow path through liner 404 so the gases can exit processing chamber 400.

The vacuum system may comprise vacuum pump 426 and throttle valve 423 to regulate flow of gases within processing chamber 400. Vacuum pump 426 is coupled to a vacuum port 418 disposed on chamber body 409, and is in fluid communication with pumping channel 402 formed within liner 404. Vacuum pump 426 and chamber body 409 are selectively isolated by throttle valve 423 to regulate flow of the gases within processing chamber 400. The terms “gas” and “gases” may be used interchangeably, unless otherwise noted, and refer to one or more precursors, reactants, catalysts, carrier, purge, cleaning, combinations thereof, as well as any other fluid introduced into chamber body 409.

The lid assembly 450 includes at least two stacked components configured to form a plasma volume or cavity therebetween. In one or more embodiments, the lid assembly 450 includes a first electrode 410 (“upper electrode”) disposed vertically above a second electrode 432 (“lower electrode”) confining a plasma volume or cavity 425 therebetween. The first electrode 410 is connected to a power source 415, such as an RF power supply, and the second electrode 432 is connected to ground, forming a capacitance between the two electrodes 410, 432.

In one or more embodiments, the lid assembly 450 includes one or more gas inlets 412 (only one is shown) that are at least partially formed within an upper section 413 of the first electrode 410. The one or more process gases enter the lid assembly 450 via the one or more gas inlets 412. The one or more gas inlets 412 are in fluid communication with the plasma cavity 425 at a first end thereof and coupled to one or more upstream gas sources and/or other gas delivery components, such as gas mixers, at a second end thereof. The first end of the one or more gas inlets 412 can open into the plasma cavity 425 at the upper most point of the inner diameter 430 of the expanding section 420. Similarly, the first end of the one or more gas inlets 412 can open into the plasma cavity 425 at any height interval along the inner diameter 430 of the expanding section 420. Although not shown, two gas inlets 412 can be disposed at opposite sides of the expanding section 420 to create a swirling flow pattern or “vortex” flow into the expanding section 420 which helps mix the gases within the plasma cavity 425.

In one or more embodiments, the first electrode 410 has an expanding section 420 that houses the plasma cavity 425. The expanding section 420 is in fluid communication with the gas inlet 412 as described above. In one or more embodiments, the expanding section 420 is an annular member that has an inner surface or diameter 430 that gradually increases from an upper portion 420A thereof to a lower portion 420B thereof. As such, the distance between the first electrode 410 and the second electrode 432 is variable. That varying distance helps control the formation and stability of the plasma generated within the plasma cavity 425.

In one or more embodiments, the expanding section 420 resembles a cone or “funnel”. In one or more embodiments, the inner surface 430 of the expanding section 420 gradually slopes from the upper portion 420A to the lower portion 420B of the expanding section 420. The slope or angle of the inner diameter 430 can vary depending on process requirements and/or process limitations. The length or height of the expanding section 420 can also vary depending on specific process requirements and/or limitations. In one or more embodiments, the slope of the inner diameter 430, or the height of the expanding section 420, or both can vary depending on the volume of plasma needed for processing. For example, the slope of the inner diameter 430 can be at least 1:1, or at least 1.5:1 or at least 2:1 or at least 3:1 or at least 4:1 or at least 5:1 or at least 10:1. In one or more embodiments, the slope of the inner diameter 430 can range from a low of 2:1 to a high of 20:1.

In one or more embodiments, the expanding section 420 can be curved or arced although not shown in the figures. For example, the inner surface 430 of the expanding section 420 can be curved or arced to be either convexed or concaved. In one or more embodiments, the inner surface 430 of the expanding section 420 can have a plurality of sections that are each sloped, tapered, convexed, or concaved.

As mentioned above, the expanding section 420 of the first electrode 410 varies the vertical distance between the first electrode 410 and the second electrode 432 because of the gradually increasing inner surface 430 of the first electrode 410. That variable distance is directly related to the power level within the plasma cavity 425. Not wishing to be bound by theory, the variation in distance between the two electrodes 410, 432 allows the plasma to find the necessary power level to sustain itself within some portion of the plasma cavity 425 if not throughout the entire plasma cavity 425. The plasma within the plasma cavity 425 is therefore less dependent on pressure, allowing the plasma to be generated and sustained within a wider operating window. As such, a more repeatable and reliable plasma can be formed within the lid assembly 450.

The first electrode 410 can be constructed from any process compatible materials, such as aluminum, anodized aluminum, nickel plated aluminum, nickel plated aluminum 6061-T6, stainless steel as well as combinations and alloys thereof, for example. In one or more embodiments, the entire first electrode 410 or portions thereof are nickel coated to reduce unwanted particle formation. Preferably, at least the inner surface 430 of the expanding section 420 is nickel plated.

The second electrode 432 can include one or more stacked plates. When two or more plates are desired, the plates should be in electrical communication with one another. Each of the plates should include a plurality of apertures or gas passages to allow the one or more gases from the plasma cavity 425 to flow through.

The lid assembly 450 can further include an isolator ring 440 to electrically isolate the first electrode 410 from the second electrode 432. The isolator ring 440 can be made from aluminum oxide or any other insulative, process compatible material. Preferably, the isolator ring 440 surrounds or substantially surrounds at least the expanding section 420.

The second electrode 432 includes a top plate 460, distribution plate 470 and blocker plate 480. The top plate 460, distribution plate 470 and blocker plate 480 are stacked and disposed on a lid rim 490 which is connected to the chamber body 409. A hinge assembly (not shown) can be used to couple the lid rim 490 to the chamber body 409. The lid rim 490 can include an embedded channel or passage 492 for housing a heat transfer medium. The heat transfer medium can be used for heating, cooling, or both, depending on the process requirements. Illustrative heat transfer mediums are listed above.

In one or more embodiments, the top plate 460 includes a plurality of gas passages or apertures 465 formed beneath the plasma cavity 425 to allow gas from the plasma cavity 425 to flow therethrough. In one or more embodiments, the top plate 460 can include a recessed portion 462 that is adapted to house at least a portion of the first electrode 410. In one or more embodiments, the apertures 465 are through the cross section of the top plate 460 beneath the recessed portion 462. The recessed portion 462 of the top plate 460 can be stair-stepped to provide a better sealed fit therebetween. Furthermore, the outer diameter of the top plate 460 can be designed to mount or rest on an outer diameter of the distribution plate 470. An o-ring type seal, such as an elastomeric o-ring 463, can be at least partially disposed within the recessed portion 462 of the top plate 460 to ensure a fluid-tight contact with the first electrode 410. Likewise, an o-ring type seal 466 can be used to provide a fluid-tight contact between the outer perimeters of the top plate 460 and the distribution plate 470.

In one or more embodiments, the distribution plate 470 is substantially disc-shaped and includes a plurality of apertures 475 or passageways to distribute the flow of gases therethrough. The apertures 475 can be sized and positioned about the distribution plate 470 to provide a controlled and even flow distribution to the chamber body 409 where the substrate to be processed is located. Furthermore, the apertures 475 prevent the gas(es) from impinging directly on the substrate surface by slowing and re-directing the velocity profile of the flowing gases, as well as evenly distributing the flow of gas to provide an even distribution of gas across the surface of the substrate.

The distribution plate 470 can also include an annular mounting flange 472 formed at an outer perimeter thereof. The mounting flange 472 can be sized to rest on an upper surface of the lid rim 490. An o-ring type seal, such as an elastomeric o-ring, can be at least partially disposed within the annular mounting flange 472 to ensure a fluid-tight contact with the lid rim 490.

In one or more embodiments, the distribution plate 470 includes one or more embedded channels or passages 474 for housing a heater or heating fluid to provide temperature control of the lid assembly 450. Similar to the lid assembly 450 described above, a resistive heating element can be inserted within the passage 474 to heat the distribution plate 470. A thermocouple can be connected to the distribution plate 470 to regulate the temperature thereof. The thermocouple can be used in a feedback loop to control electric current applied to the heating element, as described above.

Alternatively, a heat transfer medium can be passed through the passage 474. The one or more passages 474 can contain a cooling medium, if needed, to better control temperature of the distribution plate 470 depending on the process requirements within the chamber body 409. As mentioned above, any heat transfer medium may be used, such as nitrogen, water, ethylene glycol, or mixtures thereof, for example.

In one or more embodiments, the lid assembly 450 can be heated using one or more heat lamps (not shown). Typically, the heat lamps are arranged about an upper surface of the distribution plate 470 to heat the components of the lid assembly 450 including the distribution plate 470 by radiation.

The blocker plate 480 is optional and would be disposed between the top plate 460 and the distribution plate 470. Preferably, the blocker plate 480 is removably mounted to a lower surface of the top plate 460. The blocker plate 480 should make good thermal and electrical contact with the top plate 460. In one or more embodiments, the blocker plate 480 can be coupled to the top plate 460 using a bolt or similar fastener. The blocker plate 480 can also be threaded or screwed onto an out diameter of the top plate 460.

The blocker plate 480 includes a plurality of apertures 485 to provide a plurality of gas passages from the top plate 460 to the distribution plate 470. The apertures 485 can be sized and positioned about the blocker plate 480 to provide a controlled and even flow distribution the distribution plate 470.

The confinement of the plasma within the plasma cavity 425 and the central location of the confined plasma allows an even and repeatable distribution of the disassociated gas(es) into the chamber body 409. Particularly, the gas leaving the plasma volume 425 flows through the apertures 465 of the top plate 460 to the upper surface of the blocker plate 480. The apertures 485 of the blocker plate 480 distribute the gas to the backside of the distribution plate 470 where the gas is further distributed through the apertures 475 of the distribution plate 470 before contacting the substrate (not shown) within the chamber body 409. It is believed that the confinement of the plasma within the centrally located plasma cavity 425 and the variable distance between the first electrode 410 and the second electrode 432 generate a stable and reliable plasma within the lid assembly 450.

The support assembly 411 can be at least partially disposed within the chamber body 409. The support assembly 411 can include a support member 417 to support a substrate (not shown in this view) for processing within the chamber body 409. The support member 417 can be coupled to a lift mechanism 427 through a shaft 422 which extends through a centrally-located opening 421 formed in a bottom surface of the chamber body 409. The lift mechanism 427 can be flexibly sealed to the chamber body 409 by a bellows 424 that prevents vacuum leakage from around the shaft 422. The lift mechanism 427 allows the support member 417 to be moved vertically within the chamber body 409 between a process position and a lower, transfer position. The transfer position is slightly below the opening of the slit valve 405 formed in a sidewall of the chamber body 409.

In one or more embodiments, the support member 417 has a flat, circular surface or a substantially flat, circular surface for supporting a substrate to be processed thereon. The support member 417 is preferably constructed of aluminum. The support member 417 can include a removable top plate 433 made of some other material, such as silicon or ceramic material, for example, to reduce backside contamination of the substrate.

In one or more embodiments, the support member 417 or the top plate 433 can include a plurality of extensions or dimples (not shown) arranged on the upper surface thereof. The dimples can be arranged on the upper surface of the support member 417 if a top plate 433 is not desired. The dimples provide minimum contact between the lower surface of the substrate and the support surface of the support assembly 411 (i.e. either the support member 417 or the top plate 433), if minimum contact is desired.

In one or more embodiments, the substrate (not shown) may be secured to the support assembly 411 using a vacuum chuck. The top plate 433 can include a plurality of holes 434 in fluid communication with one or more grooves 435 formed in the support member 417. The grooves 435 are in fluid communication with a vacuum pump (not shown) via a vacuum conduit 436 disposed within the shaft 422 and the support member 417. Under certain conditions, the vacuum conduit 436 can be used to supply a purge gas to the surface of the support member 417 to prevent deposition when a substrate is not disposed on the support member 417. The vacuum conduit 436 can also pass a purge gas during processing to prevent a reactive gas or byproduct from contacting the backside of the substrate.

In one or more embodiments, the substrate (not shown) may be secured to the support member 417 using an electrostatic chuck. In one or more embodiments, the substrate can be held in place on the support member 417 by a mechanical clamp (not shown), such as a conventional clamp ring.

Preferably, the substrate is secured using an electrostatic chuck. An electrostatic chuck typically includes at least a dielectric material that surrounds an electrode (not shown), which may be located on an upper surface of the support member 417 or formed as an integral part of the support member 417. The dielectric portion of the chuck electrically insulates the chuck electrode from the substrate and from the remainder of the support assembly 411.

In one or more embodiments, the perimeter of the chuck dielectric can be is slightly smaller than the perimeter of the substrate. In other words, the substrate slightly overhangs the perimeter of the chuck dielectric so that the chuck dielectric will remain completely covered by the substrate even if the substrate is misaligned off center when positioned on the chuck. Assuring that the substrate completely covers the chuck dielectric ensures that the substrate shields the chuck from exposure to potentially corrosive or damaging substances within the chamber body 409.

The voltage for operating the electrostatic chuck can be supplied by a separate “chuck” power supply (not shown). One output terminal of the chucking power supply is connected to the chuck electrode. The other output terminal typically is connected to electrical ground, but alternatively may be connected to a metal body portion of the support assembly 411. In operation, the substrate is placed in contact with the dielectric portion, and a direct current voltage is placed on the electrode to create the electrostatic attractive force or bias to adhere the substrate on the upper surface of the support member 417.

The support member 417 can include one or more bores 408 formed therethrough to accommodate a lift pin 407. Each lift pin 407 is typically constructed of ceramic or ceramic-containing materials, and are used for substrate-handling and transport. Each lift pin 407 is slideably mounted within the bore 408. In one aspect, the bore 408 is lined with a ceramic sleeve to help freely slide the lift pin 407. The lift pin 407 is moveable within its respective bore 408 by engaging an annular lift ring 419 disposed within the chamber body 409. The lift ring 419 is movable such that the upper surface of the lift-pin 407 can be located above the substrate support surface of the support member 417 when the lift ring 419 is in an upper position. Conversely, the upper surface of the lift-pins 407 is located below the substrate support surface of the support member 417 when the lift ring 419 is in a lower position. Thus, part of each lift-pin 407 passes through its respective bore 408 in the support member 417 when the lift ring 419 moves from either the lower position to the upper position.

When activated, the lift pins 407 push against a lower surface of the substrate, lifting the substrate off the support member 417. Conversely, the lift pins 407 may be de-activated to lower the substrate, thereby resting the substrate on the support member 417. The lift pins 407 can include enlarged upper ends or conical heads to prevent the pins 407 from falling out from the support member 417. Other pin designs can also be utilized and are well known to those skilled in the art.

In one embodiment, one or more of the lift pins 407 include a coating or an attachment disposed thereon that is made of a non-skid or highly frictional material to prevent the substrate from sliding when supported thereon. A preferred material is a high temperature, polymeric material that does not scratch or otherwise damage the backside of the substrate which would create contaminants within the processing chamber 400. Preferably, the coating or attachment is KALREZ™ coating available from DuPont.

To drive the lift ring 419, an actuator, such as a conventional pneumatic cylinder or a stepper motor (not shown), is generally used. The stepper motor or cylinder drives the lift ring 419 in the up or down positions, which in turn drives the lift-pins 407 that raise or lower the substrate. In a specific embodiment, a substrate (not shown) is supported on the support member 417 by three lift-pins 407 (not shown in this view) dispersed approximately 120 degrees apart and projecting from the lift ring 419.

The support assembly 411 can include an edge ring 437 disposed about the support member 417. The edge ring 437 can be made of a variety of materials such as ceramic, quartz, aluminum and steel, among others. In one or more embodiments, the edge ring 437 is an annular member that is adapted to cover an outer perimeter of the support member 417 and protect the support member 417 from deposition. The edge ring 437 can be positioned on or adjacent the support member 417 to form an annular purge gas channel 438 between the outer diameter of support member 417 and the inner diameter of the edge ring 437. The annular purge gas channel 438 can be in fluid communication with a purge gas conduit 439 formed through the support member 417 and the shaft 422. Preferably, the purge gas conduit 439 is in fluid communication with a purge gas supply (not shown) to provide a purge gas to the purge gas channel 438. Any suitable purge gas such as nitrogen, argon, or helium, may be used alone or in combination. In operation, the purge gas flows through the conduit 439, into the purge gas channel 438, and about an edge of the substrate disposed on the support member 417. Accordingly, the purge gas working in cooperation with the edge ring 437 prevents deposition at the edge and/or backside of the substrate.

The temperature of the support assembly 411 is controlled by a fluid circulated through a fluid channel 414 embedded in the body of the support member 417. In one or more embodiments, the fluid channel 414 is in fluid communication with a heat transfer conduit 441 disposed through the shaft 422 of the support assembly 411. Preferably, the fluid channel 414 is positioned about the support member 417 to provide a uniform heat transfer to the substrate receiving surface of the support member 417. The fluid channel 414 and heat transfer conduit 441 can flow heat transfer fluids to either heat or cool the support member 417. Any suitable heat transfer fluid may be used, such as water, nitrogen, ethylene glycol, or mixtures thereof. The support assembly 411 can further include an embedded thermocouple (not shown) for monitoring the temperature of the support surface of the support member 417. For example, a signal from the thermocouple may be used in a feedback loop to control the temperature or flowrate of the fluid circulated through the fluid channel 414.

The support member 417 can be moved vertically within the chamber body 409 so that a distance between support member 417 and the lid assembly 450 can be controlled. A sensor (not shown) can provide information concerning the position of support member 417 within chamber 400.

In operation, the support member 417 can be elevated to a close proximity of the lid assembly 450 to control the temperature of the substrate being processed. As such, the substrate can be heated via radiation emitted from the distribution plate 470 that is controlled by the heating element of fluid disposed in the channel 474. Alternatively, the substrate can be lifted off the support member 417 to close proximity of the heated lid assembly 450 using the lift pins 407 activated by the lift ring 419.

While the foregoing is directed to embodiments of the invention, other and further embodiments of the invention may be devised without departing from the basic scope thereof.

What is claimed is:

1. A method for treating a semiconductor substrate having doped regions and undoped regions, comprising:
disposing the semiconductor substrate in a processing chamber;
providing a reactive gas mixture comprising hydrogen radicals and fluorine radicals to the processing chamber;
exposing the semiconductor substrate to the reactive gas mixture; and
etching the doped regions of the semiconductor substrate faster than the undoped regions in a carbon-free dry etch process.

2. The method of claim 1, wherein providing the reactive gas mixture comprising hydrogen radicals and fluorine radicals to the processing chamber comprises applying dissociative energy to a precursor gas mixture comprising nitrogen, hydrogen, and fluorine at a remote location to generate active species, and flowing the active species toward the processing chamber for a time sufficient to extinguish electrical charges.

3. The method of claim 1 wherein etching the doped regions of the semiconductor substrate forms volatile species including hydrides and halides.

4. The method of claim 2, wherein the precursor gas mixture comprises ammonium trifluoride and hydrogen gas.

5. The method of claim 4, wherein the precursor gas further comprises a carrier gas.

6. The method of claim 1, wherein providing the reactive gas mixture comprising hydrogen radicals and fluorine radicals to the processing chamber comprises applying RF energy to a precursor gas mixture comprising nitrogen trifluoride, hydrogen, and helium.

7. The method of claim 6, wherein a ratio of hydrogen molecules to nitrogen trifluoride molecules in the precursor gas mixture is at least 1.

8. The method of claim 6, wherein the RF energy is applied at a power level no more than 500 W.

9. The method of claim 1, wherein the reactive gas mixture selectively etches doped silicate glass at a rate at least 20% higher than undoped silicate glass.

10. The method of claim 2, wherein etching the doped regions of the semiconductor substrate faster than the undoped regions comprises reacting the hydrogen radicals with dopants implanted in the doped regions and reacting fluorine radicals with silicates in the doped and undoped regions of the semiconductor substrate.

11. The method of claim 10, wherein reacting the hydrogen radicals with dopants implanted in the doped regions comprises forming volatile compounds and removing the volatile compounds from the processing chamber.

12. The method of claim 1, wherein the reactive gas mixture further comprises hydrogen fluoride.

13. A method of processing a substrate, comprising:
disposing the substrate in a processing chamber;
depositing a doped silicate glass layer on the substrate;
depositing an undoped silicate glass layer on the substrate; and
etching the deposited layers using a carbon-free dry etch process having an etch selectivity of the doped silicate glass layer over the undoped silicate glass layer of at least 1.2.

14. The method of claim 13, wherein the carbon-free dry etch process comprises exposing the substrate to a reactive gas mixture comprising hydrogen radicals and fluorine radicals, reacting the reactive gas mixture with the substrate surface to produce volatile compounds, and removing the volatile compounds.

15. The method of claim 13, wherein the carbon-free dry etch process comprises applying RF energy to a carbon-free precursor gas mixture comprising hydrogen, nitrogen, and fluorine to form a reactive gas mixture comprising hydrogen radicals and fluorine radicals, substantially extinguishing charged species in the reactive gas mixture, and exposing the substrate to the reactive gas mixture.

16. The method of claim 15, wherein the carbon-free precursor gas mixture comprises nitrogen trifluoride and hydrogen gas.

17. The method of claim 16, wherein the carbon-free precursor gas mixture further comprises a carrier gas.

18. The method of claim 16, wherein a ratio of hydrogen molecules to nitrogen trifluoride molecules is at least about 1.

19. The method of claim 14, further comprising controlling the etch selectivity of the carbon-free dry etch process by adjusting a ratio of hydrogen radicals to fluorine radicals in the reactive gas mixture.

20. The method of claim 18, further comprising controlling the etch selectivity of the carbon-free dry etch process by adjusting the ratio of hydrogen molecules to nitrogen trifluoride molecules.

21. The method of claim 13, wherein etching the deposited layers comprises providing a first reactive gas mixture having a first etch selectivity and providing a second reactive gas mixture having a second etch selectivity.

22. The method of claim 21, wherein the first reactive gas mixture has a first ratio of hydrogen radicals to fluorine radicals, and the second reactive gas mixture has a second ratio of hydrogen radicals to fluorine radicals.

23. A method of treating a semiconductor substrate, comprising:
disposing the substrate in a substrate processing chamber;
forming a reactive gas mixture comprising neutral hydrogen radicals and fluorine radicals in a remote activation chamber;
flowing the reactive gas mixture toward a substrate processing chamber for a time interval sufficient to extinguish charged species;
exposing a surface of the substrate to the reactive gas mixture; and
smoothing defects in the surface of the substrate by reacting the reactive gas mixture with oxides and dopants in the surface of the substrate.

24. The method of claim 23, wherein forming the reactive gas mixture comprises providing a precursor gas mixture comprising nitrogen trifluoride and hydrogen gas to the remote activation chamber and applying dissociative energy to the precursor gas mixture.
